(19) United States
(12) Patent Application Publication
(10) Pub. No.: US 2025/0142769 A1
(43) Pub. Date: May 1, 2025

(54) LIQUID IMMERSION COOLING DEVICE

(71) Applicant: Panasonic Intellectual Property Management Co., Ltd., Osaka (JP)

(72) Inventors: Youji SHIRATO, Hokkaido (JP); Ryosuke USUI, Aichi (JP); Naoki SAITOU, Hokkaido (JP); Norihiro KAWAMURA, Hokkaido (JP)

(21) Appl. No.: 18/921,971

(22) Filed: Oct. 21, 2024

(30) Foreign Application Priority Data
Oct. 27, 2023 (JP) 2023-184988

(51) Int. Cl. H05K 7/20

(52) U.S. Cl. CPC H05K 7/20236; H05K 7/20263; H05K 7/20472

(57) ABSTRACT

A liquid immersion cooling device includes an electronic device and a cooling medium. The electronic device includes a circuit board, a heat generator mounted on the circuit board, a heat dissipator, and a thermal conductive sheet interposed between the heat generator and the heat dissipator. The cooling medium is arranged to immerse the electronic device at least partially. At least part of the thermal conductive sheet is made of a porous material.

### CROSS-REFERENCE TO RELATED APPLICATIONS

The present application is based upon, and claims the benefit of priority to, Japanese Patent Application No. 2023-184988, filed on Oct. 27, 2023, the entire contents of which are hereby incorporated by reference.

### TECHNICAL FIELD

The present disclosure generally relates to a liquid immersion cooling device, and more particularly relates to a liquid immersion cooling device including an electronic device and a cooling medium.

### BACKGROUND ART

WO 2006/049768 A1 discloses a liquid immersion cooling device for use to cool a heat dissipator. The liquid immersion cooling device includes a heat transfer fluid held in a hermetically sealed container. In this liquid immersion cooling device, a thermal interface material is interposed between a heat generator and the heat dissipator. For example, an indium sheet may be used as the thermal interface material.

The known liquid immersion cooling device still has room for improvement in cooling performance.

### SUMMARY

The present disclosure provides a liquid immersion cooling device having the ability to improve the cooling performance.

A liquid immersion cooling device according to an aspect of the present disclosure includes an electronic device and a cooling medium. The electronic device includes a circuit board, a heat generator mounted on the circuit board, a heat dissipator, and a thermal conductive sheet interposed between the heat generator and the heat dissipator. The cooling medium is arranged to immerse the electronic device at least partially. At least part of the thermal conductive sheet is made of a porous material.

A liquid immersion cooling device according to another aspect of the present disclosure includes an electronic device and a cooling medium. The electronic device includes a circuit board, a heat generator mounted on the circuit board, a heat dissipator, and a thermal conductive sheet interposed between the heat generator and the heat dissipator. The cooling medium is arranged to immerse the electronic device at least partially. The thermal conductive sheet has at least one selected from the group consisting of unevenness, a slit, a groove, and a pore.

A liquid immersion cooling device according to still another aspect of the present disclosure includes an electronic device and a cooling medium. The electronic device includes a circuit board, a heat generator mounted on the circuit board, a heat dissipator, and a thermal conductive sheet interposed between the heat generator and the heat dissipator. The cooling medium is arranged to immerse the electronic device at least partially. The thermal conductive sheet is made of graphite.

### BRIEF DESCRIPTION OF DRAWINGS

The figures depict one or more implementations in accordance with the present teaching, by way of example only, not by way of limitations. In the figures, like reference numerals refer to the same or similar elements.

FIG. 1 is a schematic cross-sectional view illustrating a liquid immersion cooling device according to an exemplary embodiment of the present disclosure; and

FIG. 2 is a schematic representation illustrating a liquid immersion cooling device according to another embodiment of the present disclosure.

### DETAILED DESCRIPTION

### 1. Overview

A liquid immersion cooling device 1 according to an exemplary embodiment of the present disclosure will be described with reference to the accompanying drawings. Note that the embodiment to be described below is only an exemplary one of various embodiments of the present disclosure and should not be construed as limiting. Rather, the exemplary embodiment may be readily modified in various manners depending on a design choice or any other factor without departing from a true spirit and scope of the present disclosure. The drawings to be referred to in the following description of embodiments are all schematic representations. Thus, the ratio of the dimensions (including thicknesses) of respective constituent elements illustrated on the drawings does not always reflect their actual dimensional ratio.

In the known liquid immersion cooling device described above, an indium sheet, for example, is used as the thermal interface material interposed between the heat generator and the heat dissipator. The indium sheet has no compressibility, and therefore, would be unable to fill the gap between the heat generator and the heat dissipator sufficiently. The present inventors carried out extensive research and development to overcome such a problem with the known art. As a result, the present inventors discovered that the cooling performance of the liquid immersion cooling device would be improved by using a member having particular physical properties as the thermal conductive sheet 14 interposed between the heat generator 12 and the heat dissipator 13 in the liquid immersion cooling device 1, thus conceiving the concept of the present disclosure.

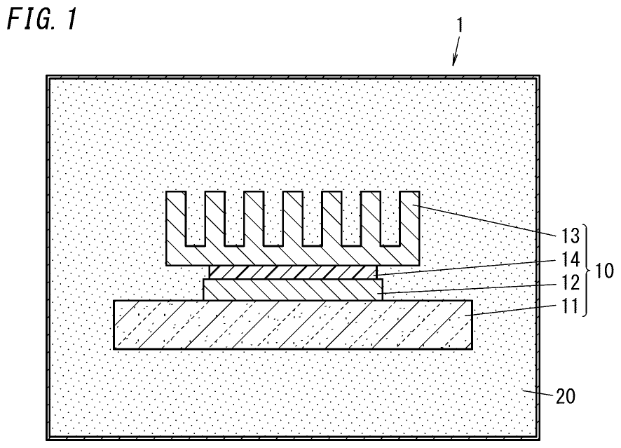

FIG. 1 is a cross-sectional view illustrating an exemplary liquid immersion cooling device 1 according to this embodiment. The liquid immersion cooling device 1 shown in FIG. 1 includes an electronic device 10 and a cooling medium 20. The electronic device 10 includes a circuit board 11, a heat generator 12 mounted on the circuit board 11, a heat dissipator 13, and a thermal conductive sheet 14 interposed between the heat generator 12 and the heat dissipator 13. The cooling medium 20 is arranged to immerse the electronic device 10 at least partially.

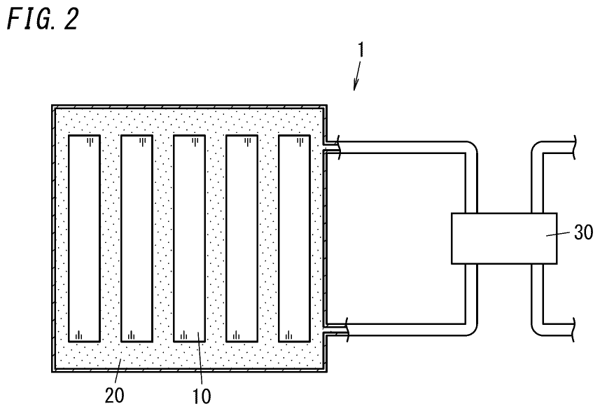

The liquid immersion cooling device 1 shown in FIG. 2 includes a plurality of (e.g., five in the example shown in FIG. 2) electronic devices 10, all of which are immersed in the cooling medium 20. In addition, the liquid immersion cooling device 1 shown in FIG. 1 further includes a heat exchanger 30. The cooling medium 20 is supplied by a pump (not shown) to, and cooled by, the heat exchanger 30 and then fed back to its original place.

In the liquid immersion cooling device 1 according to this embodiment, the thermal conductive sheet 14 is characterized by: (1) being made of a porous material at least partially; (2) having at least one selected from the group consisting of unevenness, a slit, a groove, and a pore; or (3) being made of graphite.

The liquid immersion cooling device 1 according to this embodiment improves the cooling performance. The reasons why the liquid immersion cooling device 1 achieves this advantage by using one of these configurations may be presumed, for example, as follows. Specifically, the thermal conductive sheet 14 having any one of these three features (1) to (3) may be easily collapsed into a particular shape that makes it easier to fill the gap between the heat generator 12 and the heat dissipator 13. In addition, infiltrating the thermal conductive sheet 14 with the cooling medium 20 also allows the air gaps of the thermal conductive sheet 14 to be filled. Furthermore, causing the cooling medium 20 thus infiltrated to move inside the thermal conductive sheet 14 and to the surface of the thermal conductive sheet 14 allows the thermal conductive sheet 14 to make close contact with the heat generator 12 and the heat dissipator 13. Consequently, this reduces the thermal resistance between the heat generator 12 and the heat dissipator 13. Furthermore, the cooling medium 20 is allowed to enter and leave the thermal conductive sheet 14 while the heat generator 12 is repeatedly heated and cooled. The cooling performance of the liquid immersion cooling device 1 would be improved probably by this mechanism.

Thus, the liquid immersion cooling device 1 according to this embodiment may improve the cooling performance.

### 2. Details

### <Liquid Immersion Cooling Device>

Next, a liquid immersion cooling device 1 according to this embodiment will be described in detail.

### First Embodiment

The liquid immersion cooling device 1 includes an electronic device 10 and a cooling medium 20. In the liquid immersion cooling device 1 according to the first embodiment, at least part of the thermal conductive sheet 14 is made of a porous material.

Respective constituent elements of the liquid immersion cooling device 1 will now be described one by one.

### [Electronic Device]

The electronic device 10 includes a circuit board 11, a heat generator 12, a heat dissipator 13, and a thermal conductive sheet 14. The liquid immersion cooling device 1 may include only one electronic device 10 or a plurality of electronic devices 10, whichever is appropriate.

Examples of the electronic device 10 include HDDs, DVD players, cellphones, smartphones, tablet computers, electronic control units (ECUs) for automobiles, power control units (PCUs), display devices such as a liquid crystal display, organic EL lights, solar batteries, touchscreen panels, camera modules, inverters, converters, and a blade server housing any of these devices and components such as a memory and a central processing unit (CPU) in a small casing.

### (Circuit Board)

The circuit board 11 is a board including various circuits such as an inverter circuit and a motor driver circuit for activating the electronic device 10. The electronic device 10 may include only one circuit board 11 or a plurality of circuit boards 11, whichever is appropriate. The circuit board 11 may be a single-layer board or a multilayer board, whichever is appropriate.

### (Heat Generator)

The heat generator 12 is a member that generates heat. The heat generator 12 is mounted on the circuit board 11. The heat generator 12 may be, for example, a semiconductor component. Examples of the semiconductor components include, without limitation, transistors, central processing units (CPUs), micro processing units (MPUs), driver ICs, and memories. The heat generator 12 may be made up of, for example, a heat spreader and a chip fixed on the heat spreader. The heat spreader may be a plate member made of a metal, for example. The chip may be, for example, a semiconductor package. In that case, the chip may be mounted on the heat spreader except the outer peripheral portion of the heat spreader. The outer peripheral portion may have a plurality of screw holes at respective positions corresponding to a plurality of screw holes penetrating through the heat spreader.

### (Heat Dissipator)

The heat dissipator 13 is a member to which the heat generated by the heat generator 12 is transferred. The heat may be dissipated from the heat dissipator 13. The heat dissipator 13 may be a heatsink, for example. If the heat dissipator 13 is a plate-shaped heatsink, then the heat dissipator 13 may further include radiator fins. The heat dissipator 13 may have a plurality of screw holes, for example, at respective positions corresponding to the plurality of screw holes of the heat generator 12 described above.

### (Thermal Conductive Sheet)

The thermal conductive sheet 14 is a member which transfers the heat from the heat generator 12 to the heat dissipator 13. In the liquid immersion cooling device 1 according to the first embodiment, at least part of the thermal conductive sheet 14 is made of a porous material. As used herein, the “porous material” refers to a solid having internal pores (or air gaps). As used herein, the “air gaps” refer to respective parts of the thermal conductive sheet 14 from which the constituent material for the thermal conductive sheet is absent. The pores of the porous material may be communication holes or independent holes, whichever is appropriate. The pores may or may not be connected to the surface of the thermal conductive sheet 14. The pores are preferably communication holes connected to the surface. This makes it easier for the cooling medium 20 to be infiltrated into the thermal conductive sheet 14. The air gap ratio of the thermal conductive sheet 14 is preferably equal to or greater than 30% by volume and equal to or less than 95% by volume and is more preferably equal to or greater than 50% by volume and equal to or less than 90% by volume. As used herein, the air gap ratio (% by volume) is calculated by [1−(apparent specific gravity of thermal conductive sheet/true specific gravity of constituent material for thermal conductive sheet]×100. The apparent specific gravity of the thermal conductive sheet may be calculated based on the volume and mass obtained from the external dimensions of the thermal conductive sheet. Preferably, 50% by mass or more of the thermal conductive sheet 14 is the porous material. More preferably, 90% by mass or more of the thermal conductive sheet 14 is the porous material. Even 100% by mass of the thermal conductive sheet 14 may be the porous material.

As can be seen, the thermal conductive sheet 14 has air gaps. In the liquid immersion cooling device 1, at least some of the air gaps are preferably infiltrated with the cooling medium 20. In that case, the cooling medium 20 thus infiltrated may further reduce the thermal resistance of the thermal conductive sheet 14.

The thermal conductive sheet 14 preferably has at least one structure selected from the group consisting of a sponge, a honeycomb, a fiber, and a stack. As used herein, the “sponge” refers to a structure having an infinite number of internal pores, which may be communication holes or independent holes, whichever is appropriate. The “honeycomb” as used herein refers to a structure as a bundle of a plurality of linear pores which are partitioned from each other by thin boundary walls. The cross section of each of these linear pores may have a hexagonal shape or any other suitable shape. As used herein, the “fiber” refers to a structure in which each constituent material for the thermal conductive sheet has a fibrous shape (e.g., of which the ratio of its length to its diameter is equal to or greater than 3). As used herein, the “stack” refers to a structure in which multiple layered structures are laid one on top of another.

The thermal conductive sheet 14 having any one of these structures may be easily collapsed when compressed to make it easier to fill the gap between the heat generator 12 and the heat dissipator 13, and therefore, may further reduce the thermal resistance.

The thermal conductive sheet 14 is preferably neither reactive to, nor dissolvable in, the cooling medium 20.

The thermal conductive sheet 14 preferably has a compression rate equal to or higher than 5% and equal to or lower than 95% when compressed in the thickness direction under a pressure of 200 kPa applied. This allows the gaps between the thermal conductive sheet 14, the heat generator 12, and the heat dissipator 13 to be filled more sufficiently, thus enabling further reducing the thermal resistance. The compression rate of the thermal conductive sheet 14 is more preferably equal to or higher than 20% and equal to or lower than 95% and is even more preferably equal to or higher than 30% and equal to or lower than 95%. As used herein, the “compression rate” of the thermal conductive sheet 14 refers to a percentage notation of 1−T1/T0, where T0 is the initial thickness of the thermal conductive sheet 14 and T1 is the thickness of the thermal conductive sheet 14 to which a pressure of 200 kPa has been applied.

The thermal conductive sheet 14 may have an average thickness equal to or greater than 30 μm and equal to or less than 500 μm, for example, and preferably has an average thickness equal to or greater than 50 μm and equal to or less than 200 μm. As used herein, the “average thickness” refers to an arithmetic mean of the thicknesses measured at multiple points (e.g., at arbitrary 10 points) of the thermal conductive sheet 14.

### [Cooling Medium]

The cooling medium 20 is a medium for use to cool (the heat dissipator 13, in particular, of) the electronic device 10. The cooling medium 20 is ordinarily held in a container, for example, and used with the electronic device 10 immersed in the cooling medium 20. As the cooling medium 20, an insulating liquid with excellent electrical insulation properties, for example, may be used.

Examples of the cooling medium 20 include: hydrocarbon-based oils such as hydrocarbon and poly alpha olefin (PAO); fluorine-containing oils such as perfluorocarbon, hydrofluorocarbon, hydrofluoroether, and perfluoroketone; hydrocarbon compounds such as silicone oil, alkylbenzene, alkylnaphthalene, and alkyl diphenyl alkane; and medicinal oil such as mineral oil. The cooling medium 20 preferably contains at least one of a hydrocarbon-based oil or a fluorine-containing oil.

### [Heat Exchanger]

The liquid immersion cooling device 1 normally includes a heat exchanger 30. The heat exchanger 30 exchanges heat between, for example, the cooling medium 20 supplied by a pump (not shown) and cooling water supplied by a cooling unit (not shown). This allows the temperature of the cooling medium 20 to be controlled, thus further improving the cooling performance of the liquid immersion cooling device 1.

### Second Embodiment

In a liquid immersion cooling device 1 according to a second embodiment, the thermal conductive sheet 14 has at least one selected from the group consisting of unevenness, a slit, a groove, and a pore. The liquid immersion cooling device 1 according to the second embodiment has the same configuration as the liquid immersion cooling device 1 according to the first embodiment except the thermal conductive sheet 14.

The thermal conductive sheet 14 according to the second embodiment has at least one selected from the group consisting of unevenness, a slit, a groove, and a pore. As used herein, the phrase “having unevenness” refers to not only a situation where recesses and projections are both provided but also a situation where only recesses or only projections are provided. The “slit” as used herein refers to a cut or incision having a narrow width which penetrates through the thermal conductive sheet. The “groove” as used herein refers to a linear or curvilinear opening which does not penetrate through the thermal conductive sheet. The “pore” as used herein refers to both an aperture that does not penetrate through the thermal conductive sheet and a through hole that penetrates through the thermal conductive sheet.

In the liquid immersion cooling device 1, the thermal conductive sheet 14 having such a structure may be compressed to a moderate degree and the thermal resistance between the heat generator 12 and the heat dissipator 13 may be further reduced, thus further improving the cooling performance of the liquid immersion cooling device 1.

### Third Embodiment

In a liquid immersion cooling device 1 according to a third embodiment, the thermal conductive sheet 14 is made of graphite. The liquid immersion cooling device 1 according to the third embodiment has the same configuration as the liquid immersion cooling devices 1 according to the first and second embodiment except the thermal conductive sheet 14.

The thermal conductive sheet 14 according to the third embodiment is made of graphite. As used herein, the “graphite” refers to black lead which is one of carbon allotropes and is also called “plumbago.” The graphite has a structure formed by stacking in the thickness direction, and combining with van der Waals force, multiple layers (graphene layers), in each of which carbon atoms are arranged in the shape of a hexagonal honeycomb grid by sp2 bonding. The graphite may also be, for example, a stack of multiple layers of graphite (graphite layers).

In the liquid immersion cooling device 1, the thermal conductive sheet 14 is made of graphite having such a structure, and therefore, has moderate air gaps and may be compressed to a moderate degree, thus further reducing the thermal resistance between the heat generator 12 and the heat dissipator 13. Consequently, this contributes to further improving the cooling performance of the liquid immersion cooling device 1.

### (Recapitulation)

As can be seen from the foregoing description, the present disclosure has the following aspects. In the following description, reference signs are added in parentheses to the respective constituent elements solely for the purpose of clarifying the correspondence between the following aspects of the present disclosure and the exemplary embodiments described above.

A liquid immersion cooling device (1) according to a first aspect includes an electronic device (10) and a cooling medium (20). The electronic device (10) includes a circuit board (11), a heat generator (12) mounted on the circuit board (11), a heat dissipator (13), and a thermal conductive sheet (14) interposed between the heat generator (12) and the heat dissipator (13). The cooling medium (20) is arranged to immerse the electronic device (10) at least partially. At least part of the thermal conductive sheet (14) is made of a porous material.

A liquid immersion cooling device (1) according to a second aspect includes an electronic device (10) and a cooling medium (20). The electronic device (10) includes a circuit board (11), a heat generator (12) mounted on the circuit board (11), a heat dissipator (13), and a thermal conductive sheet (14) interposed between the heat generator (12) and the heat dissipator (13). The cooling medium (20) is arranged to immerse the electronic device (10) at least partially. The thermal conductive sheet (14) has at least one selected from the group consisting of unevenness, a slit, a groove, and a pore.

A liquid immersion cooling device (1) according to a third aspect includes an electronic device (10) and a cooling medium (20). The electronic device (10) includes a circuit board (11), a heat generator (12) mounted on the circuit board (11), a heat dissipator (13), and a thermal conductive sheet (14) interposed between the heat generator (12) and the heat dissipator (13). The cooling medium (20) is arranged to immerse the electronic device (10) at least partially. The thermal conductive sheet (14) is made of graphite.

The first, second, and third aspects may reduce the thermal resistance between the heat generator (12) and the heat dissipator (13), thus improving the cooling performance of the liquid immersion cooling device (1).

In a liquid immersion cooling device (1) according to a fourth aspect, which may be implemented in conjunction with any one of the first to third aspects, the thermal conductive sheet (14) has an air gap, and at least a part of the air gap is infiltrated with the cooling medium (20).

The fourth aspect may further reduce the thermal resistance by providing the thermal conductive sheet (14) with such an air gap infiltrated with the cooling medium (20) at least partially, thus further improving the cooling performance of the liquid immersion cooling device (1).

In a liquid immersion cooling device (1) according to a fifth aspect, which may be implemented in conjunction with any one of the first to fourth aspects, the thermal conductive sheet (14) has at least one structure selected from the group consisting of a sponge, a honeycomb, a fiber, and a stack.

The fifth aspect may further reduce the thermal resistance by forming the thermal conductive sheet (14) in at least one of these structures, thus further improving the cooling performance of the liquid immersion cooling device (1).

In a liquid immersion cooling device (1) according to a sixth aspect, which may be implemented in conjunction with any one of the first to fifth aspects, the thermal conductive sheet (14) is neither reactive to, nor dissolvable in, the cooling medium (20).

The sixth aspect allows the liquid immersion cooling device (1) to maintain sufficient cooling performance.

In a liquid immersion cooling device (1) according to a seventh aspect, which may be implemented in conjunction with any one of the first to sixth aspects, the thermal conductive sheet (14) has a compression rate equal to or higher than 5% and equal to or lower than 95% when compressed in a thickness direction under a pressure of 200 kPa applied.

The seventh aspect may further reduce the thermal resistance by setting the compression rate of the thermal conductive sheet (14) at a value falling within this range, thus further improving the cooling performance of the liquid immersion cooling device (1).

In a liquid immersion cooling device (1) according to an eighth aspect, which may be implemented in conjunction with any one of the first to seventh aspects, the thermal conductive sheet (14) contains graphite.

The eighth aspect may further reduce the thermal resistance of the thermal conductive sheet (14), thus further improving the cooling performance of the liquid immersion cooling device (1).

A liquid immersion cooling device (1) according to a ninth aspect, which may be implemented in conjunction with any one of the first to eighth aspects, further includes a heat exchanger (30) for cooling the cooling medium (20).

The ninth aspect allows the liquid immersion cooling device (1) to control the temperature of the cooling medium (20) by providing the heat exchanger (30) for the liquid immersion cooling device (1), thus further improving the cooling performance of the liquid immersion cooling device (1).

While the foregoing has described what are considered to be the best mode and/or other examples, it is understood that various modifications may be made therein and that the subject matter disclosed herein may be implemented in various forms and examples, and that they may be applied in numerous applications, only some of which have been described herein. It is intended by the following claims to claim any and all modifications and variations that fall within the true scope of the present teachings.

1. A liquid immersion cooling device comprising:
an electronic device including a circuit board, a heat generator mounted on the circuit board, a heat dissipator, and a thermal conductive sheet interposed between the heat generator and the heat dissipator; and
a cooling medium arranged to immerse the electronic device at least partially,
at least part of the thermal conductive sheet being made of a porous material.

2. The liquid immersion cooling device of claim 1, wherein
the thermal conductive sheet has an air gap, and
at least a part of the air gap is infiltrated with the cooling medium.

3. The liquid immersion cooling device of claim 1, wherein
the thermal conductive sheet has at least one structure selected from the group consisting of a sponge, a honeycomb, a fiber, and a stack.

4. The liquid immersion cooling device of claim 1, wherein
the thermal conductive sheet is neither reactive to, nor dissolvable in, the cooling medium.

5. The liquid immersion cooling device of claim 1, wherein
the thermal conductive sheet has a compression rate equal to or higher than 5% and equal to or lower than 95% when compressed in a thickness direction under a pressure of 200 kPa applied.

6. The liquid immersion cooling device of claim 1, wherein
the thermal conductive sheet contains graphite.

7. The liquid immersion cooling device of claim 1, further comprising a heat exchanger configured to cool the cooling medium.

8. A liquid immersion cooling device comprising:
an electronic device including a circuit board, a heat generator mounted on the circuit board, a heat dissipator, and a thermal conductive sheet interposed between the heat generator and the heat dissipator; and
a cooling medium arranged to immerse the electronic device at least partially,
the thermal conductive sheet having at least one selected from the group consisting of unevenness, a slit, a groove, and a pore.

9. The liquid immersion cooling device of claim 8, wherein
the thermal conductive sheet has an air gap, and
at least a part of the air gap is infiltrated with the cooling medium.

10. The liquid immersion cooling device of claim 8, wherein
the thermal conductive sheet has at least one structure selected from the group consisting of a sponge, a honeycomb, a fiber, and a stack.

11. The liquid immersion cooling device of claim 8, wherein
the thermal conductive sheet is neither reactive to, nor dissolvable in, the cooling medium.

12. The liquid immersion cooling device of claim 8, wherein
the thermal conductive sheet has a compression rate equal to or higher than 5% and equal to or lower than 95% when compressed in a thickness direction under a pressure of 200 kPa applied.

13. The liquid immersion cooling device of claim 8, wherein
the thermal conductive sheet contains graphite.

14. The liquid immersion cooling device of claim 8, further comprising a heat exchanger configured to cool the cooling medium.

15. A liquid immersion cooling device comprising:
an electronic device including a circuit board, a heat generator mounted on the circuit board, a heat dissipator, and a thermal conductive sheet interposed between the heat generator and the heat dissipator; and
a cooling medium arranged to immerse the electronic device at least partially,
the thermal conductive sheet being made of graphite.

16. The liquid immersion cooling device of claim 15, wherein
the thermal conductive sheet has an air gap, and
at least a part of the air gap is infiltrated with the cooling medium.

17. The liquid immersion cooling device of claim 15, wherein
the thermal conductive sheet has at least one structure selected from the group consisting of a sponge, a honeycomb, a fiber, and a stack.

18. The liquid immersion cooling device of claim 15, wherein
the thermal conductive sheet is neither reactive to, nor dissolvable in, the cooling medium.

19. The liquid immersion cooling device of claim 15, wherein
the thermal conductive sheet has a compression rate equal to or higher than 5% and equal to or lower than 95% when compressed in a thickness direction under a pressure of 200 kPa applied.

20. The liquid immersion cooling device of claim 15, further comprising a heat exchanger configured to cool the cooling medium.
